(19) United States
(12) Patent Application Publication
(10) Pub. No.: US 2016/0056261 A1
(43) Pub. Date: Feb. 25, 2016

(54) EMBEDDED SIGMA-SHAPED SEMICONDUCTOR ALLOYS FORMED IN TRANSISTORS

(71) Applicant: GLOBALFOUNDRIES INC., GRAND CAYMAN (KY)

(72) Inventors: Hans-Juergen Thees, Dresden (DE); Jens-Peter Biethan, Friedberg (DE)

(21) Appl. No.: 14/466,004

(22) Filed: Aug. 22, 2014

(51) Int. Cl. H01L 29/66; H01L 21/02; H01L 29/06; H01L 29/51; H01L 21/311; H01L 29/78; H01L 21/306; H01L 29/423

(52) U.S. Cl. CPC H01L 29/6656; H01L 21/30604; H01L 21/02636; H01L 29/42364; H01L 29/513; H01L 29/518; H01L 21/31116; H01L 29/78; H01L 29/0657; H01L 21/02532

(57) ABSTRACT

A method of forming a semiconductor device is disclosed wherein sigma-shaped cavities are formed in alignment with a gate structure such that a cavity tip of the sigma-shaped cavities has a small lateral distance to the channel region, while a lateral distance from the silicon-germanium material filled into the cavity and extending along the sidewall of the gate structure above the active region is at least maintained, if not increased. A semiconductor device is formed wherein the semiconductor device comprises a gate structure disposed over an active region of a semiconductor substrate. The gate structure has a gate electrode and a sidewall spacer structure with a first spacer of L-shape and a second spacer disposed on the first spacer. In alignment with the gate structure, sigma-shaped cavities are formed in the active region and embedded SiGe material is epitaxially grown in the sigma-shaped cavities.

### BACKGROUND OF THE INVENTION

1. Field of the Invention

Generally, the present disclosure relates to the fabrication of integrated circuits, and, more particularly, to transistors comprising sigma-shaped embedded semiconductor materials, such as embedded semiconductor alloys, so as to enhance charge carrier mobility in the channel regions of the transistors.

2. Description of the Related Art

In modern electronic equipment, integrated circuits (ICs) experience a vast applicability in a continuously spreading range of applications. Particularly, the demand for increasing mobility of electronic devices at high performance and low energy consumption drives developments to more and more compact devices having features with sizes ranging even into the deep submicron regime; the more so as current semiconductor technologies are apt of producing structures with dimensions in the magnitude of 10 nm. With ICs representing a set of electronic circuit elements integrated on a semiconductor material, normally silicon, ICs can be made much smaller than discreet circuits composed of independent circuit components. The majority of present-day ICs are implemented by using a plurality of semiconductor devices as circuit elements, such as field effect transistors (FETs), also called metal oxide semiconductor field effect transistors (MOSFETs or simply MOS transistors) and passive elements, such as resistors and capacitors, integrated on a semiconductor substrate with a given surface area. Typically, present-day integrated circuits involve millions of single circuit elements formed on a semiconductor substrate.

The basic function of a MOSFET is that of an electronic switching element, wherein a current through a channel region between two contact regions, referred to as source and drain, is controlled by a gate electrode to which a voltage relative to source and drain is applied. Particularly, in applying a voltage exceeding a characteristic voltage level to the gate electrode, the conductivity state of a MOSFET is changed and the characteristic voltage level, usually called “threshold voltage” and in the following referred to as Vt, characterizes the switching behavior of a MOSFET. In general, Vt depends nontrivially on the transistor's properties, e.g., materials, dimensions etc., such that the implementation of a desired Vt involves plural steps of adjustment and fine-tuning during the fabrication process.

In efforts to continuously reduce the size of MOSFETs, i.e., the gate length of the transistors, it has been proposed to enhance the channel conductivity of the transistor elements by increasing the charge carrier mobility in the channel region for a given channel length, thereby enabling a performance improvement that is comparable with the advance to a technology standard requiring extremely scaled critical dimensions, while avoiding or at least postponing many of the process adaptations associated with device scaling.

One efficient mechanism for increasing the charge carrier mobility is the modification of the lattice structure in the channel region, for instance by creating tensile or compressive stress in the vicinity of the channel region so as to produce a corresponding strain in the channel region, which results in a modified mobility for electrons and holes, respectively. For example, creating tensile strain in the channel region for a standard crystallographic configuration of the active silicon material, i.e., a (100) surface orientation with the channel length aligned to the <110> direction, increases the mobility of electrons, which, in turn, may directly translate into a corresponding increase in conductivity. On the other hand, compressive strain in the channel region may increase the mobility of holes, thereby providing the potential for enhancing the performance of P-type transistors. The introduction of stress or strain engineering into integrated circuit fabrication is an extremely promising approach, since strained silicon may be considered as a “new” type of semiconductor material, which may enable the fabrication of fast powerful semiconductor devices without requiring expensive semiconductor materials, while many of the well-established manufacturing techniques may still be used.

With regard to PMOS devices it has been proposed to introduce, for instance, a silicon-germanium (SiGe) material next to the channel region so as to induce a compressive stress that may result in a corresponding strain. Silicon-germanium material is in general an alloy Si₁₋ₓGeₓ which consists of any molar ratio of silicon and germanium. In known techniques, the drain and source regions of the PMOS transistors are selectively recessed when forming the SiGe material to form cavities, while the NMOS transistors are masked. Subsequently, the silicon-germanium material is selectively formed in the cavities of the PMOS transistor by epitaxial growth.

This approach results in an improved transistor performance of P-channel transistors or PMOS devices since drive current capability and switching speed are enhanced. Generally, the effect of the strain-inducing mechanism provided by the embedded silicon-germanium alloy strongly depends on the material composition of the silicon-germanium alloy, i.e., on the germanium concentration, since an increased amount of germanium in the alloy results in a greater lattice mismatch between the natural lattice constant of silicon-germanium and the lattice constant of the silicon base material. On the other hand, according to presently available selective deposition recipes for forming the silicon-germanium alloy, the germanium concentration may not be arbitrarily increased, since significant lattice defects may be created, thereby offsetting the advantages that should be obtained by providing the silicon-germanium alloy in a highly strained state. Consequently, in other approaches, the efficiency of the strain-inducing mechanism is increased for a given germanium concentration of the alloy by appropriately dimensioning the cavity that is formed laterally adjacent to the gate electrode structure, thereby increasing the amount of strained material that may finally act on the adjacent channel region. Moreover, the lateral offset or generally the proximity of the strained silicon-germanium alloy to the channel region may also significantly affect the finally achieved strain conditions in the channel region so that, in sophisticated approaches, it is attempted to continuously reduce the lateral offset of the cavities and, thus, of the silicon-germanium alloy from the channel region. To this end, appropriate etch techniques may be applied in combination with appropriate protective liner materials provided at sidewalls of the gate electrode structures in order to further reduce the lateral offset of the resulting cavities.

A conventional process flow for forming embedded SiGe regions is described below with regard to FIGS. 1a-1d. FIG. 1a shows a semiconductor device 100 during a conventional process flow. At the depicted stage during fabrication, the semiconductor device 100 comprises a gate structure 120 disposed on an active region 110 which is provided within a semiconductor substrate. The gate structure 120 comprises, in accordance with FIG. 1a, a gate electrode 122, a sidewall spacer 126 and a gate cap 124 formed on an upper surface of the gate electrode 122, while the sidewalls of the gate electrode 122 are covered by the sidewall spacer 126. The sidewall spacer 126 is used to register source/drain extension regions 112 formed within the active region 110 in alignment with the gate structure 120 when implanting dopants into the semiconductor substrate, and particularly into the active region 110. That is, the gate structure 120 is used as an aligning masking pattern for the source/drain extension regions 112. Alternatively or additionally, halo regions 114 may be formed adjacent to the source/drain extension regions 112 for adjusting the threshold voltage. As known in the art, halo regions 114 represent counter-doped regions with a high dopant concentration relative to the source/drain extension regions 112.

After the implantation of the source/drain extension regions 112 and the halo regions 114, a spacer-forming material 128′ is deposited over the gate electrode 120, wherein the spacer-forming semiconductor material 128′ covers the gate structure 120 and the source/drain extension regions 112.

Next, the deposited spacer-forming material 128′ is patterned by means of an RIE process such that, in a first step, a spacer 128 is formed adjacent to the sidewall spacer 126 and, in a second step, trenches 130 are etched into the active region 110 in accordance with the gate structure 120. As illustrated in FIG. 1b, the spacer 128 adjusts a lateral extension of the source/drain extension regions 112. Then, a cleaning step (not illustrated) is performed.

Next, as illustrated in FIG. 1c, a wet etch process 132 is applied for forming sigma-shaped cavities 134 from the early-formed trenches 130 such that the sigma-shaped cavities 134 are in alignment with the gate structure 120. Herein, a first step for removing any native oxide on silicon is performed by applying diluted HF (DHF) to the trenches 130, followed by a second step using a TMAH/KOH chemistry to form the sigma-shaped cavities 134.

Next, as illustrated in FIG. 1d, a silicon-germanium material is epitaxially grown in the sigma-shaped cavities 134 for forming embedded SiGe regions 136 within the active region 110. A cavity tip of the sigma-shaped embedded SiGe region 136 is denoted by the reference numeral “T1”. A depth of the cavity tip Ti is indicated in FIG. 1d by a parameter “y”. A lateral distance between the cavity tip T1 and the gate electrode or the channel extending along the gate length, indicated by L in FIG. 1d, is denoted by a parameter “x”. A combined thickness of the sidewall spacer 126 and the spacer 128 is indicated by a parameter “z”. The parameters x, y and z, therefore, define the geometry of the sigma-shaped cavity 134 and of the SiGe regions 136.

The process 132 represents a chemical etch recipe which results in a crystallographically anisotropic etch behavior. That is, a certain type of crystal planes act as efficient “etch stop” planes which, when exposed during the etch process, significantly slow down the progress of material removal, while the etch process advances in other crystal directions with higher etch rates. Therefore, well-defined etch conditions are achieved in dependence on the basic crystallographic configuration of the semiconductor material in the active region, which has a self-limiting lateral etch behavior. For example, in a standard silicon configuration with a (100) crystal plane as a surface plane and a [110] axis oriented along the current flow direction in the corresponding channel regions, the <111> crystal planes act as etch stop planes. As the <111> crystal planes and the (100) crystal plane form an angle of about 54.7°, a well-defined inclination of the sidewalls in the cavity is achieved.

Returning to the geometric parameters x, y and z parameterizing the geometry of the sigma-shaped cavity, it is observed that the parameters are not independent from each other. Instead, a large parameter y implies a small parameter x and vice versa. Furthermore, with the parameter x clearly depending on the parameter z, the parameter y implicitly depends on the parameter z. It is important to note that any change in one parameter affects the other parameters.

As pointed out above, the embedded SiGe region 136 imposes strain on the channel, thereby creating stress in the channel region and accordingly increasing the mobility of carriers within the channel region and the device performance of PMOS devices is enhanced. In order to obtain an optimum strain imposed by the embedded silicon-germanium regions 136 to the channel region, the position of the cavity tip T1 should, therefore, be as close as possible to the transistor channel, thus implying small parameters x and y. A small parameter y indicates a small depth of the cavity tip T1 and also a vertical proximity of the cavity tip T1 to the channel region which is disposed close to an upper surface of the active region 110 below the gate electrode 122. A small parameter x indicates a small lateral distance to the gate electrode 122 and the channel region, respectively. Another constraint is derived from the demand to build up a sufficient amount of stress which constrains the volume of the embedded SiGe regions 136 to be sufficiently large and therefore contradicts small x and y values.

Another problem is set by the parasitic capacitance induced between the gate electrode and the SiGe material extending along the sidewall of gate structures. For example, in applications to ring oscillators, the PMOS ring oscillator delay increasingly degrades with increasing total gate capacitance to which the capacitance between the gate and the SiGe material extending along the sidewalls of the gate structure contributes. In order to suppress this capacitance, the distance from the SiGe material extending along the sidewalls of the gate structure 120 needs to be large, which requires a large parameter z. With a large parameter z in turn implying a large value for parameter x, it is clear the task of suppressing this parasitic capacitance contradicts the requirement of a close proximity of the cavity tip to the channel region in the framework of the conventional process flow and structure, as described with regard to FIGS. 1a-1d above.

In view of the above problems, it is desirable to provide a method of forming a semiconductor device and a semiconductor device which allows an enhanced PMOS performance by embedded SiGe regions and suppressing parasitic gate capacitances which, for example, degrade the PMOS ring oscillator delay.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure provides a method of forming a semiconductor device and a semiconductor device wherein sigma-shaped cavities are formed in alignment with a gate structure such that a cavity tip of the sigma-shaped cavities has a small lateral distance to the channel region, while a lateral distance from the silicon-germanium material filled into the cavity and extending along the sidewall of the gate structure above the active region is at least maintained, if not increased.

In one aspect of the present disclosure, a method of forming a semiconductor device is provided. In an illustrative embodiment herein, the method includes providing a gate structure disposed over an active region of a semiconductor substrate, the gate structure having a gate electrode and a sidewall spacer structure which comprises a first spacer of substantially L-shape and a second spacer disposed on the first spacer, and forming sigma-shaped cavities in the active region aligned with the gate structure. Embedded SiGe material is epitaxially grown in the sigma-shaped cavities.

In another aspect of the present disclosure, a semiconductor device is provided. In an illustrative embodiment herein, the semiconductor device includes a gate structure disposed over an active region of a semiconductor substrate, the gate structure having a gate electrode and a sidewall spacer structure which comprises a first spacer of substantially L-shape and a second spacer disposed on the first spacer, and sigma-shaped cavities filled with SiGe material formed in the active region in alignment with the gate structure, wherein the first spacer is pulled back or under-etched at a region between the second spacer and the active region such that the second spacer directly rests on a portion of the SiGe material that extends below the second spacer.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1d schematically show a conventional process flow for forming embedded SiGe regions in alignment with a gate structure; and

FIGS. 2a-2d schematically show, in accordance with illustrative embodiments of the disclosure, a process flow for forming embedded SiGe regions in alignment with a gate structure.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

The present disclosure relates to semiconductor circuit elements comprising semiconductor devices that are integrated on or in a chip, such as FETs, e.g., MOSFETs or MOS devices. When referring to MOS devices, the person skilled in the art will appreciate that, although the expression “MOS device” is used, no limitation to a metal-containing gate material and/or to an oxide-containing gate dielectric material is intended.

Semiconductor circuit elements of the present disclosure, and particularly semiconductor devices as illustrated by means of some illustrative embodiments, concern elements and devices which are fabricated by using advanced technologies. Semiconductor circuit elements of the present disclosure are fabricated by technologies applied to approach technology nodes smaller than 100 nm, for example smaller than 50 nm or smaller than 35 nm. The person skilled in the art will appreciate that the present disclosure suggests semiconductor circuit elements having structures with minimal length and/or width dimensions smaller than 100 nm, for example smaller than 50 nm or smaller than 35 nm.

The person skilled in the art understands that semiconductor devices may be fabricated as MOS devices such as P-channel MOS transistors or PMOS transistors and N-channel transistors or NMOS transistors, and both may be fabricated with or without mobility-enhancing stressor features or strain-inducing features. A circuit designer may mix and match device types, using PMOS and NMOS devices, stressed and unstressed, to take advantage of the best characteristics of each device type as they best suit the semiconductor circuit element being designed.

In the following, semiconductor circuit elements and methods of forming semiconductor circuit elements in accordance with various exemplary embodiments of the present disclosure are illustrated and described with regard to the figures. The described process steps, procedures and materials are to be considered only as exemplary embodiments designed to illustrate to one of ordinary skill in the art methods for practicing the invention. However, it is to be understood that the invention is not exclusively limited to the illustrated and described exemplary embodiments, as many possible modifications and changes exist which will become clear to the ordinary person skilled in the art when studying the present detailed description together with the accompanying drawings and the above background and summary of the invention. Illustrated portions of semiconductor devices may include only a single element, although those skilled in the art will recognize that actual implementations of semiconductor devices may include a large number of such elements. Various steps in the manufacture of semiconductor devices are well known and so, in the interests of brevity, many conventional steps will only be mentioned briefly herein, or will be omitted entirely without providing the well-known process details.

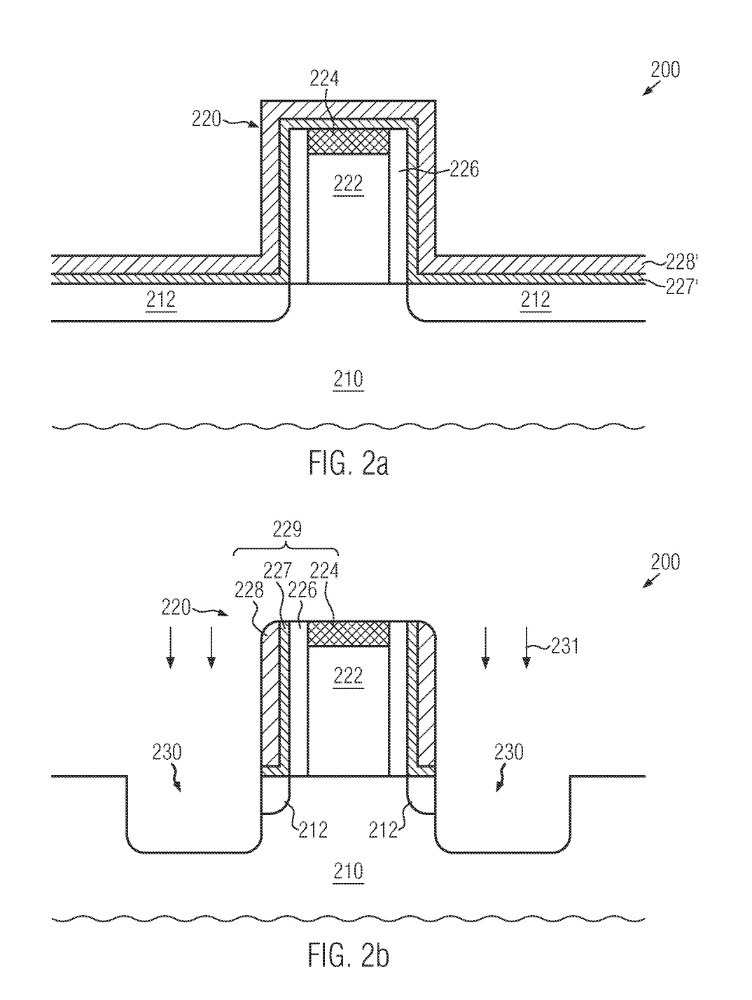

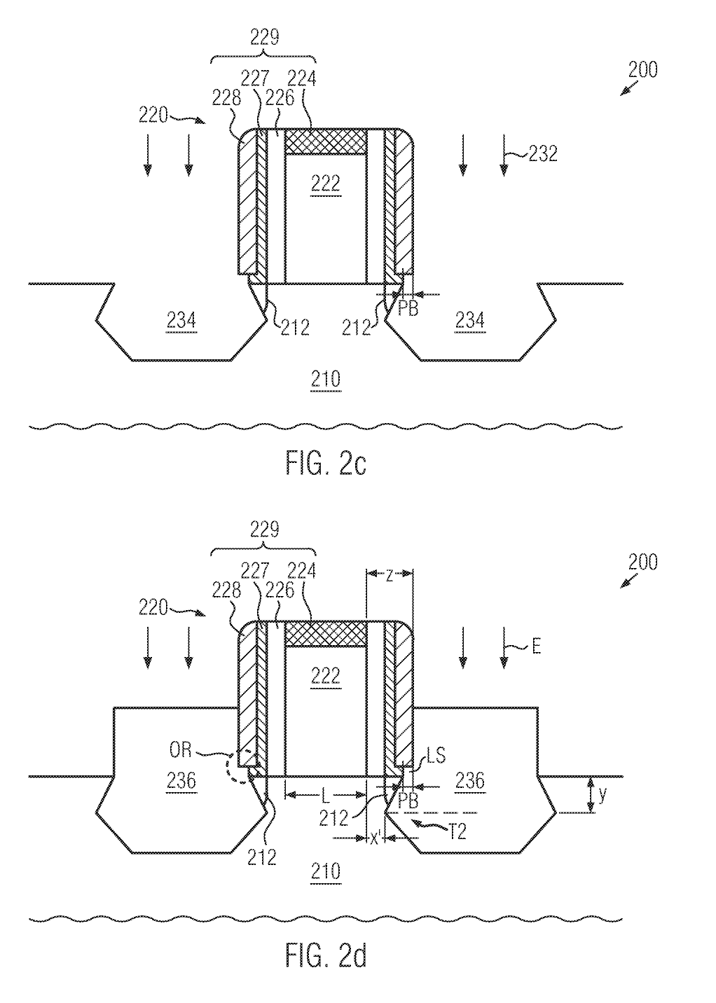

FIG. 2a schematically shows, in a cross-sectional view, a semiconductor device 200 comprising a gate structure 220 disposed on an active region 210 which is provided within a semiconductor substrate. The person skilled in the art will appreciate that the active region 210 may be provided within a semiconductor substrate in a bulk configuration or in an active layer of a silicon-on-insulator (SOI) substrate or silicon-germanium-on-insulator (SGOT) substrate. In general, the terms “substrate,” “semiconductor substrate” or “semiconducting substrate” should be understood to cover all semiconductor materials and all forms of such semiconductor materials and no limitation to a specific configuration and/or material is intended.

The gate structure 220 comprises a gate electrode 222, a gate cap 224 disposed on an upper surface of the gate electrode 222 and a sidewall spacer 226 formed adjacent to the gate electrode 222 so as to cover sidewalls of the gate electrode 222. The gate electrode 222 may represent a dummy gate in gate-last techniques and replacement gate techniques, respectively, or may include a stacked layer configuration providing a gate oxide, work function-adjusting material layer, and the gate metal, as known in the art in accordance with gate-first techniques. The person skilled in the art appreciates that known gate oxides may be provided by high-k materials, such as hafnium oxide materials and the like.

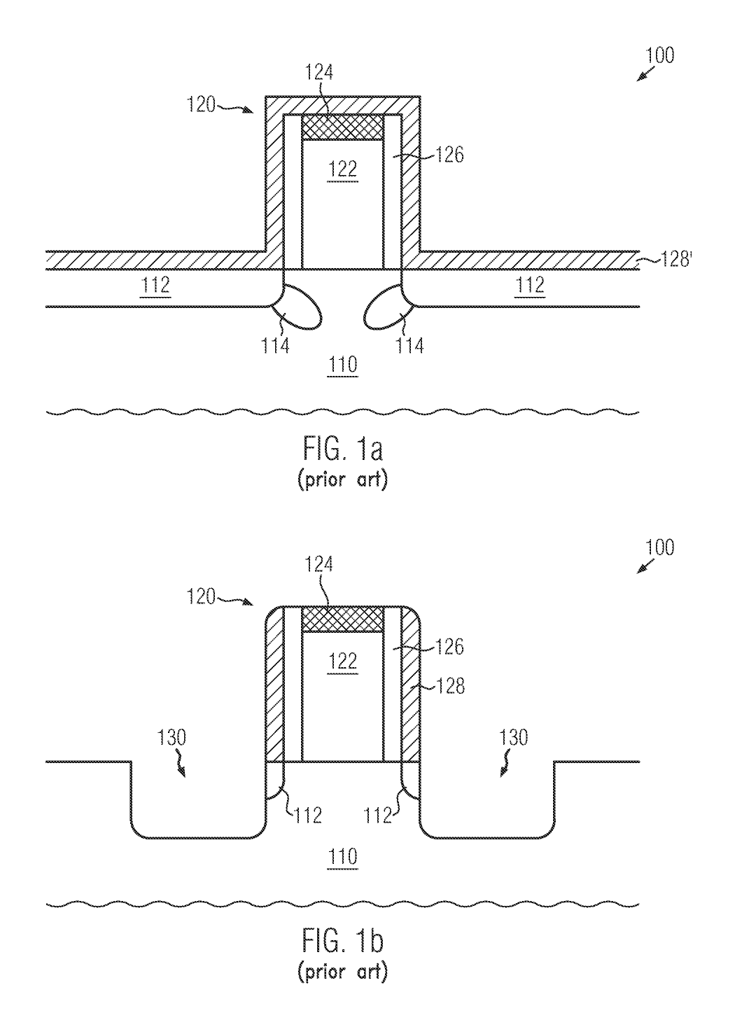

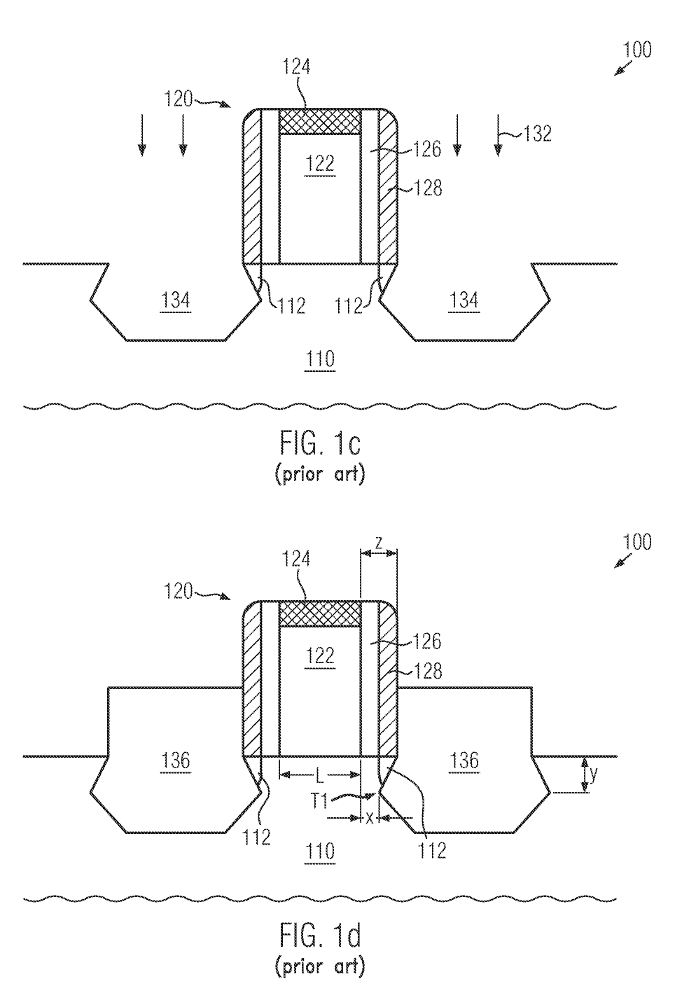

The semiconductor device 200 further comprises source/drain extension regions 212 disposed within the active region 210 close to an upper surface of the active region 210 at opposing sides of the gate structure 220 in alignment with the sidewall spacer 226. Particularly, the sidewall spacer 226 adjusts a distance from the source/drain extension regions 212 to the gate electrode 222. Optional halo regions may be present in analogy to the configuration shown in FIG. 1a, although halo regions are not explicitly illustrated in FIG. 2a.

Subsequently to the implantation of the source/drain extension regions 212, a first spacer material 227′ is deposited over the gate structure 220 and the active region 210. Particularly, the gate structure 220 and the source/drain extension regions 212 are covered by the deposited first spacer material 227′. By means of another deposition process, a second spacer material 228′ is deposited on the first spacer material 227′. The first and second spacer materials 227′ and 228′ may be deposited by means of chemical vapor deposition (CVD) processes, such as LPCVD (low pressure CVD) or PECVD (plasma enhanced CVD), for example.

In one illustrative example, the first spacer material 227′ is silicon oxide which is deposited via an LPCVD process. The second spacer material 228′ is given by silicon nitride which may be deposited by LPCVD or PECVD. In an alternative example, the first spacer material 227′ is silicon nitride and the second spacer material 228′ is silicon oxide.

In some alternative embodiments, the first spacer material 227′ may represent a native oxide of previously formed layers. Herein, no additional deposition process for depositing the first spacer material 227′ may be necessary.

In some explicit examples herein, the first spacer material 227′ may have a thickness of less than 10 nm, such as in a range from about 0-6 nm. The second spacer material 228′ may have a thickness of about 6-20 nm, such as from about 6-14 nm. In some special illustrative embodiments, the second spacer material 228′ may be deposited with a thickness that is greater by up to 10 nm as compared to the known layer 128′ of the known process flow described above with regard to FIGS. 1a-1d. For example, the second spacer material 228′ may have a thickness that is greater by up to 6 nm relative to the conventional layer 128′.

After the deposition of the first spacer material 227′ and the second spacer material 228′, the first and second spacer materials 227′ and 228′ are patterned in a patterning process 231 (FIG. 2b). The patterning process 231 may comprise an anisotropic etch process applied to the semiconductor device 200 to shape the first and second spacer material layers 227′, 228′ such that a first spacer 227 of substantially L-shaped is formed, which is covered by a second spacer 228 formed from the second spacer material 228′. Herein, a vertical extension of the first spacer 227 on the active region 210 and particularly on the source/drain extension regions 212, along a vertical direction away from the gate electrode 222, is adjusted by the second spacer 228. Therefore, the substantially L-shape of the first spacer 227 depends on a thickness of the second spacer 228 and the anisotropy of the patterning process 231.

During various stages of the process 231, the second spacer material 228′ is etched to expose a portion of the first spacer material 227′ which is disposed on the source/drain extension regions 212. During a subsequent stage within the process 231, the first spacer material 227′ is etched such that a portion of the source/drain extension regions 212 is exposed. During a further subsequent stage within the process 231, the active region 210 is anisotropically etched in alignment with the previously-shaped first and second spacer materials 227′ and 228′, i.e., the first spacer 227 and the second spacer 228. Accordingly, trenches 230 are formed within the active region 210 in alignment with the gate structure 220. Particularly, a lateral separation between the trenches 230 and the gate electrode 222 is adjusted by the sidewall spacer 226, the first spacer 227 and the second spacer 228. Due to the first spacer 227 and the second spacer 228, remanent source/drain extension regions 212 are present after the process 231 is completed. In some illustrative embodiments of the present disclosure, the process 231 may comprise an RIE etch process for forming the second spacer 228, shaping the first spacer 227, and etching the trenches 230 into the active region 210.

After completion of the process 231, the semiconductor device comprises a gate structure 220 with a spacer structure 229 covering the gate electrode 222 and remanent source/drain extension regions 212 disposed within the active region 210 below the first spacer 227. At opposing sides of the gate structure 220, the gate trenches 230 are formed within the semiconductor material 210. After the process 231, a cleaning process (not illustrated) is performed.

Next, as illustrated in FIG. 2c, a wet etch process 232 is applied to the trenches 230 (FIG. 2b) for forming sigma-shaped cavities 234 from the trenches 230 within the active region 210. In general, the wet etch process 232 is configured such that an etch rate of the wet etch process 232 relative to the first spacer 227 is substantially higher than an etch rate of the wet etch process 232 with regard to the second spacer 228. In illustrative embodiments of the present disclosure, the wet etch process 232 comprises a step of applying a first etch chemistry to the trenches 230 in FIG. 2b, and subsequently a second step of applying a second etch chemistry to the trenches for forming the sigma-shaped cavities 234. For example, the second etch chemistry may comprise TMAH/KOH.

In some illustrative embodiments with the first spacer material being of silicon oxide material and the second spacer material being of silicon nitride, the first etch chemistry comprises HF. In other illustrative embodiments with the first spacer material being of silicon nitride material and the second spacer material being of silicon oxide, the first etch chemistry comprises hot phosphoric acid, wherein the selectivity relative to silicon oxide is 10:1, relatively low as compared to the selectivity of an etching process of etching silicon oxide with HF relative to silicon nitride. Furthermore, the etch rate of PECVD silicon nitride is (at a temperature of 156° C.) higher than the etch rate of LPCVD silicon nitride.

During the first step upon exposing the trench 230 to the first etch chemistry, the first spacer 227 is exposed to the first etch chemistry resulting in an etching of the first spacer 227 relative to the second spacer 228. As illustrated in FIG. 2c, a pull-back PB of the first spacer 227 along the vertical direction below the second spacer 228 is obtained or, in other words, the first spacer 227 is partly under-etched by the first step and the selective etching of the first spacer 227 leads to a slight under-etching of the second spacer 228 in a proximity to an edge of the trench 230 close to the gate structure 220. Due to the pull-back PB caused by the first etch chemistry, the edge of the trench is displaced along a direction towards and below the second spacer 228 such that the second etch chemistry will start etching at the displaced edge. Consequently, the (111) plane limiting the etching of the trenches will start at a displaced position and therefore the geometry of the sigma-shaped cavities 234 is changed relative to the conventional sigma-shaped cavities 134 in the known process described with regard to FIG. 1c above. The implications of the new geometry will be discussed below in greater detail.

Next, as illustrated in FIG. 2d, an epitaxial growth process E is performed to fill the sigma-shaped cavities 234 with silicon-germanium material such that embedded SiGe regions 236 are formed. In overfilling the sigma-shaped cavities 234, SiGe caps or overfilling portions are formed that raise above the surface of the active region 210 such that a portion of sidewall surfaces of the second spacer 228 are covered by SiGe material extending along the sidewalls of the second spacer 228 and the gate structure 220, respectively. Due to the pull-back PB of the first spacer 227, an overlapping region OR, indicated by dashed lines in FIG. 2d, is created in which the second spacer 228 is partly disposed directly on the SiGe material of the embedded SiGe regions 236. The overlapping regions, therefore, represent SiGe material regions which partly extend below the second spacer 228 and contact the second spacer 228 from below a portion LS of a lower surface of the second spacer 228.

With the pull-back PB displacing the starting point of the (111) plane, which limits the etching of the sigma etching process 232 vertically below the second spacer 228 towards the gate electrode 222, a tip portion T2 of the sigma-shaped cavities, hereinafter referred to as cavity tip T2, is moved closer to the gate electrode 222 as compared to the conventional cavity tip T1 indicated in FIG. 1d. Therefore, a lateral distance from the cavity tip T2 to the gate electrode 222, as indicated by the parameter x′ in FIG. 2d, is smaller than the corresponding parameter x as indicated in FIG. 1d. At the same time, the depth of the cavity tip T2, indicated by a parameter y, is not influenced by the pull-back PB. Therefore, effectively, the parameter x′ is reduced relative to its known counterpart x such that the cavity tip T2 is positioned closer to the transistor channel than in the known semiconductor device 100 (FIG. 1d).

At the same time, the parameter z representing the lateral separation between the overfilling region and the gate electrode 222 is maintained, if not increased, depending on the overall thickness of the combined spacers 226, 227 and 228. The person skilled in the art will appreciate that, in choosing an increased thickness of the second spacer 228 as compared to conventional spacers 118, for example an increased thickness relative to the conventional spacer 118 by up to 6 nm, the capacitance between the gate electrode 222 and the overfilling region is decreased such that, for example, ring oscillator delay is not degraded. The person skilled in the art will appreciate that in processes in accordance with the present disclosure, the cavity tip proximity of embedded silicon-germanium can be set independently from the spacer structure.

The present disclosure, therefore, allows enhancing the performance of PMOS devices by eSiGe stress, which increases the mobility of charge carriers in the channel of PMOS devices. This is achieved by moving cavity tip positions of sigma-shaped cavities in close proximity to the transistor channel, while the volume of embedded SiGe material is not reduced and the distance between the gate electrode and any silicon-germanium material extending along sidewalls of the spacers is maintained, if not increased.

The present disclosure suggests tuning the SiGe proximity of tip portions and the capacitance of raised SiGe portions to the gate electrode independently from each other. Therefore, the speed of ring oscillators/devices may be increased, for instance.

In summary, the present disclosure provides for a method of forming a semiconductor device and a semiconductor device wherein sigma-shaped cavities are formed in alignment with a gate structure such that a cavity tip of the sigma-shaped cavities has a small lateral distance to the channel region, while a lateral distance from the silicon-germanium material filled into the cavity and extending along the sidewall of the gate structure above the active region is at least maintained, if not increased. In one aspect of the present disclosure, a semiconductor device is formed wherein the semiconductor device comprises a gate structure disposed over an active region of a semiconductor substrate. The gate structure has a gate electrode and a sidewall spacer structure with a first spacer of L-shape and a second spacer disposed on the first spacer. In alignment with the gate structure, there are sigma-shaped cavities formed in the active region and embedded SiGe material is epitaxially grown in the sigma-shaped cavities.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a semiconductor device, the method comprising:
providing a gate structure disposed over an active region of a semiconductor substrate, said gate structure having a gate electrode and a sidewall spacer structure which comprises a first spacer of substantially L-shape and a second spacer disposed on said first spacer;
forming sigma-shaped cavities in said active region aligned with said gate structure; and
epitaxially growing embedded SiGe material in said sigma-shaped cavities.

2. The method of claim 1, wherein forming said sigma-shaped cavities comprises forming trenches within said active region and exposing said trenches to an etch process for forming said sigma-shaped cavities from said trenches, wherein an etch rate of said first spacer under said etch process is higher than an etch rate of said second spacer under said etch process.

3. The method of claim 2, wherein exposing said trenches to said etch process comprises exposing said trenches to a first etch chemistry comprising HF and subsequently to a second etch chemistry comprising TMAH/KOH.

4. The method of claim 1, wherein said first spacer is formed of silicon oxide and has a thickness of less than 10 nm.

5. The method of claim 4, wherein said second spacer is formed of silicon nitride and has a thickness of at most 20 nm.

6. The method of claim 1, wherein said first spacer is partly removed from underneath said second spacer during the forming of said sigma-shaped cavities such that said first spacer is pulled back relative to said second spacer.

7. The method of claim 6, wherein said first spacer is pulled back by about 1-4 nm.

8. The method of claim 1, wherein said first spacer is formed after implanting source/drain extension regions into said active region and prior to forming deep source/drain regions in said active region.

9. The method of claim 1, wherein said spacer structure is formed by depositing an oxide layer over said gate electrode, depositing a nitride layer on said oxide layer and patterning said oxide layer and said nitride layer.

10. The method of claim 9, wherein said nitride layer is patterned by an RIE process.

11. The method of claim 10, wherein said oxide layer is patterned by said RIE process.

12. The method of claim 11, wherein a trench is formed in said active region during said RIE process, said trench being aligned with said gate structure.

13. The method of claim 12, wherein said trench is exposed to a wet etch process for forming said sigma-shaped cavities.

14. The method of claim 13, wherein said wet etch process comprises an etch step using a first etch chemistry comprising HF and an etch strep using a second etch chemistry comprising TMAH/KOH.

15. A semiconductor device, comprising:
a gate structure disposed over an active region of a semiconductor substrate, said gate structure having a gate electrode and a sidewall spacer structure which comprises a first spacer with an L-shape and a second spacer disposed on said first spacer; and
sigma-shaped cavities filled with SiGe material formed in said active region in alignment to said gate structure;
wherein said first spacer is pulled back at a region between said second spacer and said active region such that said second spacer directly rests on a portion of said SiGe material that extends below said second spacer.

16. The semiconductor device of claim 15, wherein said first spacer is pulled back relative to said second spacer by less than 5 nm.

17. The semiconductor device of claim 15, wherein said first spacer has a thickness of 10 nm or less.

18. The semiconductor device of claim 17, wherein said first spacer has a thickness of 4 nm or less.

19. The semiconductor device of claim 15, further comprising a sidewall spacer that is located between said gate electrode and said first spacer and source/drain extension regions formed in said active region in alignment to said sidewall spacer.

20. The semiconductor device of claim 15, wherein a lateral distance between a cavity tip of said sigma-shaped cavities and said gate electrode is smaller than a combined thickness of said sidewall spacer and said first spacer.
